(19) United States
(12) Patent Application Publication
(10) Pub. No.: US 2018/0305563 A1
(43) Pub. Date: Oct. 25, 2018

(54) LIQUID METAL MIXTURE AND METHOD OF FORMING A CONDUCTIVE PATTERN USING THE SAME

(71) Applicant: ELECTRONICS AND TELECOMMUNICATIONS RESEARCH INSTITUTE, Daejeon (KR)

(72) Inventors: Ji-Young OH, Daejeon (KR); Rae-Man PARK, Daejeon (KR); Kyung Hyun KIM, Daejeon (KR); Hyun Woo DANG, Daejeon (KR); Yong Suk YANG, Daejeon (KR); Kyu Sung LEE, Seoul (KR)

(21) Appl. No.: 15/954,484

(22) Filed: Apr. 16, 2018

(30) Foreign Application Priority Data
Apr. 19, 2017 (KR) 10-2017-0050665
Sep. 5, 2017 (KR) 10-2017-0113536

(51) Int. Cl. C09D 5/24; C09D 101/02; C09D 129/04; C09D 133/02; C09D 127/16; C09D 7/61; H05K 1/09; H05K 3/12; H01B 1/22

(52) U.S. Cl. CPC C09D 5/24; C09D 101/02; C09D 129/04; C09D 133/02; C09D 127/16; H05K 1/028; H05K 1/095; H05K 3/1258; H05K 3/1283; H01B 1/22; C09D 7/61

(57) ABSTRACT

Provided are a liquid metal mixture, and a method of forming a conductive pattern using the same. The liquid metal mixture includes a polymer powder of about 10 to about 90 wt %, and a liquid metal included in an amount of about 10 to about 90 wt % and covering surfaces of particles of the polymer powder, wherein the polymer powder has a polar functional group. The method includes preparing a liquid metal mixture, forming a first pattern on a substrate with the liquid metal mixture, and forming a second pattern by pressing or heating the first pattern.

### CROSS-REFERENCE TO RELATED APPLICATIONS

This U.S. non-provisional patent application claims priority under 35 U.S.C. § 119 of Korean Patent Application Nos. 10-2017-0050665, filed on Apr. 19, 2017, and 10-2017-0113536, filed on Sep. 5, 2017, the entire contents of which are hereby incorporated by reference.

### BACKGROUND

The present disclosure herein relates to a liquid metal mixture, and method of forming a conductive pattern using the same.

A eutectic alloy is a crystalline mixture of two or more of metals, or of intermetallic compounds, and is characterized in that the melting point thereof is lower than the original melting points of the metals or the intermetallic compounds constituting the alloy. Particularly, in the case of a binary system, the melting point of the composition having the composition ratio at which the components are simultaneously melted is referred to as a eutectic point. Using such a low melting point thereof, a eutectic alloy has been mainly used in the form of solder paste as a medium for mounting components of a printed circuit board in the surface-mount technology.

In the future, electronic devices of a new concept, such as an electronic device to be attached to a human body and electronic devices to be implemented on clothing in the form of a wearable electronic device, or an electronic device to be inserted into a human body, are expected to be developed. In order to develop such a wearable electronic device, it is essential to develop a stretchable electronic device which is flexible and extendable to replace a typical rigid electronic device. It is also necessary to develop conductive paste which may be applied thereto.

### SUMMARY

The present disclosure provides a liquid metal mixture capable of being applied to a flexible device.

The present disclosure also provides a method of forming a conductive pattern capable of being applied in a manufacturing process of a flexible device.

An embodiment of the inventive concept provides a liquid metal mixture including a polymer powder of about 10 to about 90 wt %; and a liquid metal included in an amount of about 10 to about 90 wt % and covering surfaces of particles of the polymer powder. The polymer powder has a polar functional group.

In an embodiment, the liquid metal may have a melting point of about −50° C. to about +100° C.

In an embodiment, the liquid metal may be at least one selected from eutectic GaIn (EGaIn), Bi₃₅In_{48.6}Sn₁₆Zn_{0.4}, a BiInSn alloy, and a GaInSn alloy.

In an embodiment, the polar functional group may be an alcohol group, a carboxyl group, or a halogen group.

In an embodiment, the polymer powder may be at least one selected from a thermoplastic polymer, cellulose, poly(vinyl alcohol), poly(acrylic acid), and polyvinylidene fluoride.

In an embodiment, the polymer powder may have a particle size of about 1 nm to about 50 μm.

In an embodiment, the mixture may further include a binder powder linking the polymer powder.

In an embodiment, the binder powder may be at least one selected from ethyl cellulose, polyvinyl acetate-polyvinylpyrrolidone, and poly(ethylene glycol).

In an embodiment, the liquid metal mixture may further include a solvent for dissolving the binder powder, and the solvent may be included in an amount of about 10 to about 100 wt % based on the sum of the weight of the polymer powder and the weight of the liquid metal.

In an embodiment, the solvent may be at least one selected from water, alcohol, ethanol, and toluene.

In an embodiment of the inventive concept, a method of forming a conductive pattern includes preparing a liquid metal mixture; forming a first pattern on a substrate with the liquid metal mixture; and forming a second pattern by pressing or heating the first pattern. The preparing of the liquid metal mixture includes mixing a polymer powder and a liquid metal to coat particles of the polymer powder with the liquid metal, and the second pattern includes the polymer powder and the liquid metal. The liquid metal fills a space among the particles of the polymer powder, and is continuous in the second pattern so that the second pattern is characterized in exhibiting conductivity.

In an embodiment, the preparing of the liquid metal mixture may further include mixing a binder powder with the polymer powder and the liquid metal.

In an embodiment, the preparing of the liquid metal mixture may further include mixing a solvent with the polymer powder, the liquid metal, and the binder powder.

In an embodiment, the forming of the first pattern on the substrate may be performed by supplying the liquid metal mixture through a dispensing, screen printing, bar coating, or ink-jet printing method.

In an embodiment, the substrate may include a trench, and the second pattern may fill the trench.

In an embodiment, the method may further include forming an adhesive layer on the substrate, and the second pattern may be formed on the adhesive layer.

In an embodiment, the pressing of the first pattern may be performed by at least one method of hand pressing, lamination, or high pressure press.

In an embodiment, the polymer powder may include a thermoplastic polymer, and the heating of the first pattern may connect the particles of the thermoplastic polymer to each other. The method may further include cooling the second pattern.

In an embodiment, the forming of the first pattern and the forming of the second pattern may be simultaneously performed by a 3D printer.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a process flow chart sequentially showing a method of forming a conductive pattern according to embodiments of the inventive concept;

FIGS. 2 and 3 are process sectional views sequentially showing a method of forming a conductive pattern according to embodiments of the inventive concept;

FIGS. 4 and 5 are process sectional views according to embodiments of the inventive concept;

FIG. 6 is an SEM photograph of a liquid metal mixture 1 prepared in Preparation Example 1;

FIG. 7 is an SEM photograph of a conductive film 1 prepared in Preparation Example 1; and

FIG. 8 is a process sectional view according to embodiments of the inventive concept.

### DETAILED DESCRIPTION

Objects, other objects, features, and advantages of the inventive concept described above may be understood easily with reference to the exemplary embodiments and the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

In the present specification, when an element is referred to as being on another element, the element may be directly formed on another element, or a third element may be interposed therebetween. In addition, in the drawings, the thickness of components is exaggerated for an effective description of the technical content.

Embodiments described in the present specification will be described with reference to cross-sectional views and/or plan views which are ideal illustrations of the inventive concept. In the drawings, the thickness of films and regions are exaggerated for an effective explanation of the technical content. Thus, the shape of the illustrations may be modified by manufacturing techniques and/or tolerances. Accordingly, the embodiments of the inventive concept are not limited to the specific shapes illustrated, but are intended to include changes in the shapes generated according to a manufacturing process. For example, an etching region shown at a right angle may be rounded or may have a shape with a predetermined curvature. Thus, the regions illustrated in the drawings have properties, and the shapes of the regions illustrated in the drawings are intended to exemplify specific shapes of regions of a device and are not intended to limit the scope of the inventive concept. Although the terms first, second, and the like are used in various embodiments of the inventive concept to describe various components, these components should not be limited by these terms. These terms are only used to distinguish one element from another. The embodiments described and exemplified herein also include the complementary embodiments thereof.

The terms used herein are for the purpose of describing embodiments and are not intended to be limiting of the inventive concept. In the present specification, singular forms include plural forms unless the context clearly indicates otherwise. The terms “comprise” and/or “comprising” used in the specification do not exclude the presence or addition of one or more other elements.

Hereinafter, exemplary embodiments of the inventive concept will be described in detail with reference to the accompanying drawings.

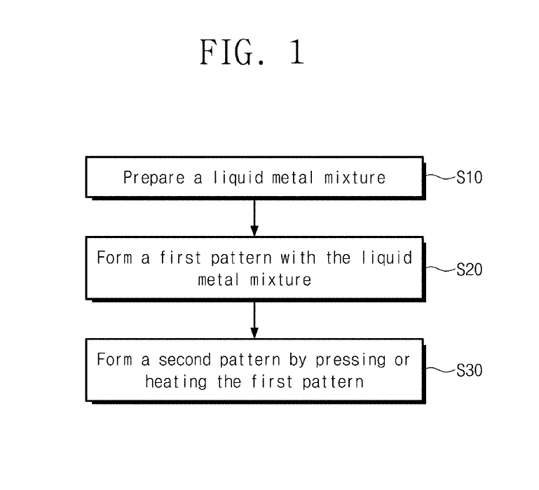

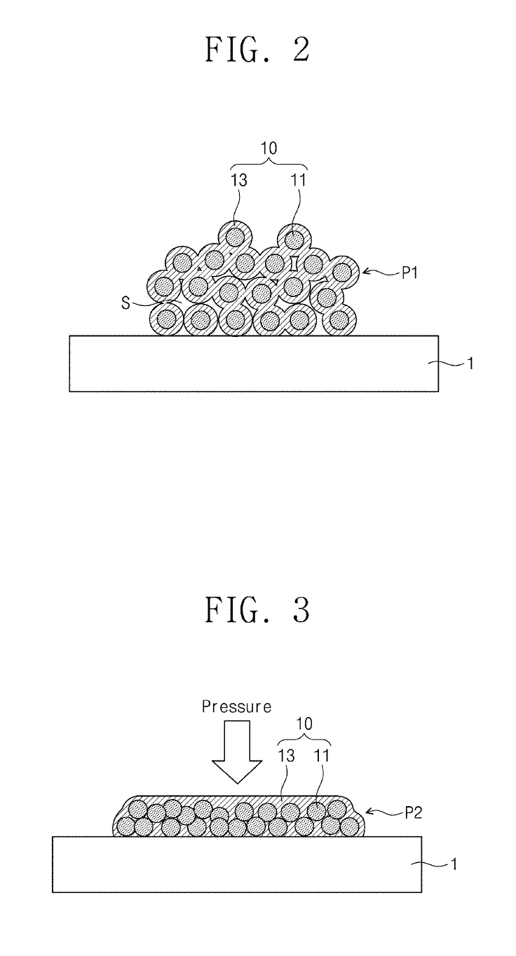

FIG. 1 is a process flow chart sequentially showing a method of forming a conductive pattern according to embodiments of the inventive concept. FIGS. 2 and 3 are process sectional views sequentially showing a method of forming a conductive pattern according to embodiments of the inventive concept.

Referring to FIGS. 1 and 2, first, a liquid metal mixture is prepared (S10). A liquid metal mixture 10 may be prepared by mixing a polymer powder 11 and a liquid metal 13. The polymer powder 11 may be included in an amount of about 10 to about 90 wt % based on the total weight of the liquid metal mixture 10. The liquid metal 13 may be included in an amount of about 10 to about 90 wt % based on the total weight of the liquid metal mixture 10. The liquid metal 13 may be mixed with the polymer powder 11 to cover surfaces of particles of the polymer powder 11. That is, the surfaces of the particles of the polymer powder 11 may be coated with the liquid metal 13. The polymer powder 11 may be preferably composed of polymers having a polar functional group. The polar functional group may be an alcohol group, a carboxyl group, or a halogen group. The polymer powder 11 may be at least one selected from a thermoplastic polymer, cellulose, poly(vinyl alcohol), poly(acrylic acid), and polyvinylidene fluoride. The thermoplastic polymer may be at least one of polyethylene, polystyrol, polyamide, and polyvinyl.

The polymer powder 11 may have a particle size of about 1 nm to about 50 μm. The liquid metal 13 may have a melting point of about −50° C. to about +100° C. The liquid metal 13 may be a metal including at least one of gallium (Ga) and indium (In), or an alloy thereof.

The liquid metal 13 may be at least one selected from eutectic GaIn (EGaIn), Bi₃₅In_{48.6}Sn₁₆Zn_{0.4}, a BiInSn alloy, and a GaInSn alloy. The EGaIn may include 75% of Ga and 25% of In. The melting point of the EGaIn may be about 15.7° C. The melting point of the Bi₃₅In_{48.6}Sn₁₆Zn_{0.4} may be about 58.3° C. When the liquid metal 13 is liquid at room temperature as EGaIn, the process of mixing the liquid metal 13 and the polymer powder 11 may be performed at room temperature. When the liquid metal 13 has a melting point higher than room temperature as Bi₃₅In_{48.6}Sn₁₆Zn_{0.4}, the process of mixing the liquid metal 13 and the polymer powder 11 may be performed at a temperature higher than the melting point. In order to provide the polymer powder 11, a process of grinding a polymer material to particulate size may be performed using a ball-mill and the like.

For example, if the liquid metal 13 is EGaIn, when exposed to air, a thin film of Ga₂O₃ having a thickness of 1 nm may be formed on a surface of the liquid metal 13. At this time, hydrogen bonding may occur between the gallium oxide thin film and the polar functional group of the polymer so that the surfaces of the particles of the polymer powder 11 may be easily coated with the liquid metal 13.

In the preparing of the liquid metal mixture 10 (S10), a binder powder may be further mixed with the polymer powder 11 and the liquid metal 13. The binder powder may be included in an amount of 10 to 100% based on the weight of the polymer powder 11. In addition, the liquid metal mixture 10 may include the binder powder instead of the polymer powder 11. In the preparing of the liquid metal mixture 10 (S10), a solvent may be further mixed with the polymer powder 11, the liquid metal 13, and the binder powder. The solvent may dissolve the binder powder. That is, the liquid metal mixture 10 may further include the binder powder and the solvent. The solvent may be included in an amount of about 10 to about 100 wt % based on the sum of the weight of the polymer powder 11 and the weight of the liquid metal 13. The binder powder may be at least one selected from ethyl cellulose, polyvinyl acetate-polyvinylpyrrolidone, and poly(ethylene glycol). In order to provide the binder powder, a process of grinding a binder material to particulate size may be performed using a ball-mill and the like. The solvent may be at least one selected from water, alcohol, ethanol, and toluene. The solvent is not limited thereto, and may vary. The liquid metal mixture 10 may be prepared and used in the form of conductive paste by the addition of the solvent. The viscosity of the liquid metal mixture 10 may be controlled according to the addition amount of the solvent and the binder powder. The liquid metal mixture 10 including the binder powder and the solvent is fluid, and thus may be used as paste. The binder powder may function as an adhesive. Alternatively, the liquid metal mixture 10 may include an adhesive in addition to the polymer powder 11 and the liquid metal 13.

Referring to FIGS. 1 and 2, a first pattern P1 may be formed on a substrate 1 by supplying the liquid metal mixture 10 (S20). The liquid metal mixture 10 may be supplied through a dispensing, screen printing, bar coating, or ink-jet printing method. The particles of the polymer powder 11 are not agglomerated in the first pattern P1, and thus an empty space S in which the liquid metal 13 does not exist may be present among the particles of the polymer powder 11. Thus, the liquid metal 13 may be discontinuous in the first pattern P1, and the electric resistance of the first pattern P1 may be high. As a result, the first pattern P1 may not be immediately used as a conductive pattern. A side surface and an upper surface of the first pattern P1 may not be flat and may be somewhat atypical. The substrate 1 may vary such as paper, clothing, a plastic substrate, a flexible substrate, glass, and the like.

Referring to FIGS. 1 to 3, a second pattern P2 may be formed by pressing or heating the first pattern P1 (S30). First, the pressing of the first pattern P1 will be described.

The pressing of the first pattern P1 (S30) may be performed by at least one method of hand pressing, lamination, or high pressure press. By pressing the first pattern P1, the liquid metal 13 may fill a space among the particles of the polymer powder 11, and thus become continuous in the second pattern P2. As a result, the electric resistance of the second pattern P2 is lowered so that the second pattern P2 may exhibit conductivity. Due to the pressing, the thickness of the second pattern P2 may become smaller than that of the first pattern P1, and the width of the second pattern P2 may be larger than that of the first pattern P1. In addition, an upper surface of the second pattern P2 may become flat.

When the liquid metal mixture 10 includes a binder powder and a solvent, the solvent may be removed by being evaporated/volatilized after the second pattern P2 is formed, and the binder powder may connect the particles of the polymer powder 11.

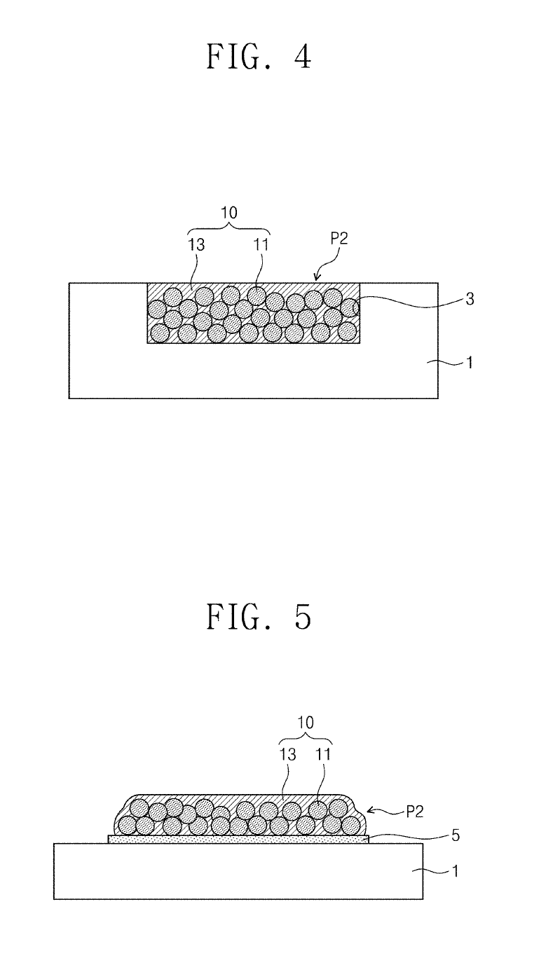

FIGS. 4 and 5 are process sectional views according to embodiments of the inventive concept.

Referring to FIGS. 2 and 4, a trench 3 may be formed on the substrate 1. Thereafter, the liquid metal mixture 10 may be supplied in the trench 3 such that the first pattern P1 fills the trench 3 and is pressed to form the second pattern P2.

Referring to FIGS. 2 and 5, an adhesive layer 5 may be disposed on the substrate 1. The liquid metal mixture 10 is supplied on the adhesive layer 5 and pressed such that the second pattern P2 may be formed on the adhesive layer 5.

Alternatively, when the liquid metal mixture 10 includes an adhesive or a binder, the liquid metal mixture 10 may be fixed on a surface of the substrate 1 without the adhesive layer 5.

A liquid metal mixture according to embodiments of the inventive concept may be allowed to have both properties of solid and liquid by coating surfaces of particles of a polymer powder with a liquid metal. That is, the liquid metal mixture looks like solid on the outside but may have liquid metal properties by including a liquid metal. When the liquid metal mixture is pressed, the liquid metal is connected to form a conductive pattern. In addition, by using a polymer powder, the content of the liquid metal may be controlled, and thus the cost may be reduced. In an embodiment of the inventive concept, the liquid metal is solidified so that the processibility is excellent. In addition, the liquid metal mixture may be mixed with a binder powder and a solvent to be used in the form of paste. In addition, the liquid metal mixture may be easily deformed, and thus may be easily applied to a flexible device. In addition, the content of the liquid metal may be controlled such that the liquid metal mixture may be used for a low-priced wiring.

On the other hand, when only a liquid metal is used without a polymer powder, the liquid state is not maintained so that the formation of a pattern may be difficult.

Next, preparation examples of the inventive concept will be described.

### Preparation Example 1

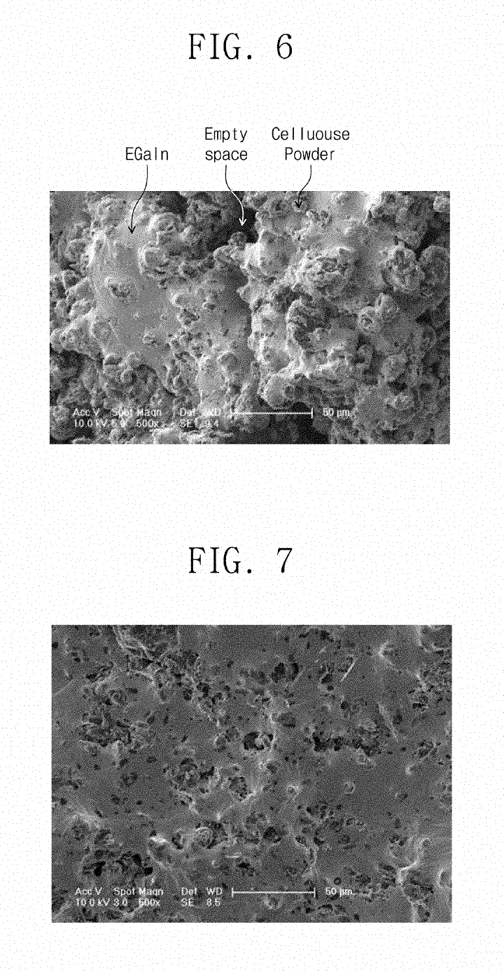

1 g of cellulose powder was prepared in a container. 1 g of EGaIn was added thereto and mixed well with the cellulose powder to prepare a liquid metal mixture 1. The liquid metal mixture 1 was placed on glass and pressed at room temperature to form a conductive film 1, and the surface resistance thereof was measured. SEM photographs of the liquid metal mixture 1 and the conductive film 1 are respectively shown in FIGS. 6 and 7. In FIG. 6, an empty space is shown among polymer powders before the pressing, but in FIG. 7, it can be seen that EGaIn is continuously connected.

### Preparation Example 2

1.3 g of cellulose powder was prepared in a container. 1 g of EGaIn was added thereto and mixed well with the cellulose powder to prepare a liquid metal mixture 2. The liquid metal mixture 2 was placed on glass and pressed at room temperature to form a conductive film 2, and the surface resistance thereof was measured.

### Preparation Example 3

1.5 g of cellulose powder was prepared in a container. 1 g of EGaIn was added thereto and mixed well with the cellulose powder to prepare a liquid metal mixture 3. The liquid metal mixture 3 was placed on glass and pressed at room temperature to form a conductive film 3, and the surface resistance thereof was measured.

The results of Preparation Examples 1 to 3 are shown in Table 1 below.

TABLE 1

| | Preparation | Preparation | Preparation |
|---|---|---|---|
| | Example 1 | Example 2 | Example 3 |
| Surface resistance | 0.050 | 0.183 | 0.201 |
| [Ω/square] | | | |

Referring to Table 1, as the amount of cellulose powder to be mixed with 1 g of EGaIn was increased from 1 g to 1.5 g, the surface resistance thereof was increased.

### Preparation Example 4

1 g of poly(vinyl alcohol) powder was prepared in a container. 1 g of EGaIn was added thereto and mixed well with the poly(vinyl alcohol) powder to prepare a liquid metal mixture 4. The liquid metal mixture 4 was placed on glass and pressed at room temperature to form a conductive film 4, and the surface resistance thereof was measured.

### Preparation Example 5

1 g of poly(acrylic acid) powder was prepared in a container. 1 g of EGaIn was added thereto and mixed well with the poly(acrylic acid) powder to prepare a liquid metal mixture 5. The liquid metal mixture 5 was placed on glass and pressed at room temperature to form a conductive film 5, and the surface resistance thereof was measured.

### Preparation Example 6

1 g of polyvinylidene fluoride powder was prepared in a container. 1 g of EGaIn was added thereto and mixed well with the polyvinylidene fluoride powder to prepare a liquid metal mixture 6. The liquid metal mixture 6 was placed on glass and pressed at room temperature to form a conductive film 6, and the surface resistance thereof was measured.

The results of Preparation Examples 4 to 6 are shown in Table 2 below.

TABLE 2

| | Preparation | Preparation | Preparation |
|---|---|---|---|
| | Example 4 | Example 5 | Example 6 |
| Surface resistance | 0.862 | 0.104 | 0.617 |
| [Ω/square] | | | |

Referring to Table 2, the surface resistance changes according to the type of a polymer powder to be mixed with 1 g of EGaIn.

### Preparation Example 7

0.8 g of cellulose powder as a polymer powder, and 0.2 g of poly(ethylene glycol) powder as a binder powder were prepared in a container. 1 g of EGaIn was added thereto and mixed well with the cellulose powder and the poly(ethylene glycol) powder to prepare a liquid metal mixture 7. The liquid metal mixture 7 was placed on glass and pressed at room temperature to form a conductive film 7, and the surface resistance thereof was measured.

### Preparation Example 8

0.5 g of cellulose powder as a polymer powder, and 0.1 g of ethyl cellulose powder as a binder powder were prepared in a container. 1 g of EGaIn was added thereto and mixed well with the cellulose powder and the ethyl cellulose powder to prepare a liquid metal mixture 8. The liquid metal mixture 8 was placed on glass and pressed at room temperature to form a conductive film 8, and the surface resistance thereof was measured.

The results of Preparation Examples 7 and 8 are shown in Table 3 below.

TABLE 3

| | Preparation | Preparation |
|---|---|---|
| | Example 7 | Example 8 |
| Surface resistance | 0.308 | 0.088 |
| [Ω/square] | | |

Referring to Table 3, when the amount of polymer powder and binder powder to be mixed is decreased with respect to the same amount of EGaIn, the surface resistance is reduced, thereby increasing the conductivity.

The liquid metal mixtures 1 to 8 prepared in Preparation Examples 1 to 8 all showed similar properties to a metallic powder to the naked eye before the pressing.

### Preparation Example 9

0.5 g of cellulose powder as a polymer powder, and 0.1 g of ethyl cellulose powder as a binder powder were prepared in a container. 1 g of EGaIn was added thereto and mixed well with the cellulose powder and the ethyl cellulose powder. Thereafter, ethanol and toluene were mixed in a volume ratio of 80:20 to prepare a solvent, and 2 ml of the solvent was added to the mixture and mixed well to prepare a liquid metal mixture 9. The liquid metal mixture 9 was similar to paste to the naked eye.

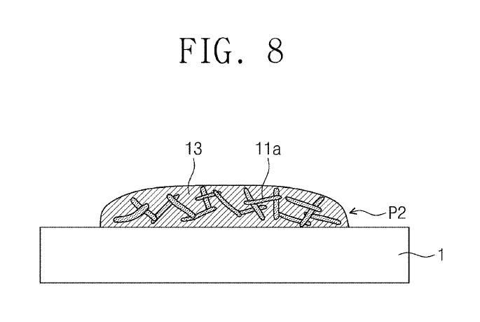

FIG. 8 is a process sectional view according to embodiments of the inventive concept.

Referring to FIGS. 2 and 8, the first pattern P1 may be heated in the state of FIG. 2. At this time, the polymer power 11 may be a thermoplastic polymer. The polymer powder 11 may be melted and rearranged by the heating, and as a result, may have a shape of being connected to each other 11a, and the liquid metal 13 coated on a surface of the polymer powder 11a may be connected to each other. Thereafter, cooling is performed at room temperature to form the second pattern P2 having conductivity. The heating temperature may be, for example, about 100 to about 150° C.

When a 3D printer is used, the process of forming the first pattern P1 in FIG. 2, and the process of forming the second pattern P2 in FIG. 8 may be simultaneously performed. That is, since a heater is present at a nozzle of a 3D printer, the liquid metal mixture is supplied and heated at the same time through the nozzle to form a conductive pattern in a 3D shape. The 3D-shaped conductive pattern may be, for example, a conductive filament.

A liquid metal mixture according to embodiment of the inventive concept may be allowed to have both properties of solid and liquid by coating surfaces of particles of a polymer powder with a liquid metal. When a conductive pattern is formed using the liquid metal mixture, the formation of a pattern is facilitated and the deformation of the liquid metal mixture is also facilitated so that the liquid metal mixture may be easily applied to a flexible device. In addition, the content of the liquid metal may be controlled such that the liquid metal mixture may be used for a low-priced wiring.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A liquid metal mixture comprising:
a polymer powder of about 10 to about 90 wt %; and
a liquid metal included in an amount of about 10 to about 90 wt % and covering surfaces of particles of the polymer powder, wherein
the polymer powder has a polar functional group.

2. The liquid metal mixture of claim 1, wherein the liquid metal has a melting point of about −50° C. to about +100° C.

3. The liquid metal mixture of claim 1, wherein the liquid metal is at least one selected from eutectic GaIn (EGaIn), Bi₃₅In_{48.6}Sn₁₆Zn_{0.4}, a BiInSn alloy, and a GaInSn alloy.

4. The liquid metal mixture of claim 1, wherein the polar functional group is an alcohol group, a carboxyl group, or a halogen group

5. The liquid metal mixture of claim 1, wherein the polymer powder is at least one selected from a thermoplastic polymer, cellulose, poly(vinyl alcohol), poly(acrylic acid), and polyvinylidene fluoride.

6. The liquid metal mixture of claim 1, wherein the polymer powder has a particle size of about 1 nm to about 50 μm.

7. The liquid metal mixture of claim 1, wherein the mixture further comprises a binder powder linking the polymer powder.

8. The liquid metal mixture of claim 7, wherein the binder powder is at least one selected from ethyl cellulose, polyvinyl acetate-polyvinylpyrrolidone, and poly(ethylene glycol).

9. The liquid metal mixture of claim 7 further comprising a solvent for dissolving the binder powder, wherein the solvent is included in an amount of about 10 to about 100 wt % based on the sum of the weight of the polymer powder and the weight of the liquid metal.

10. A method of forming a conductive pattern, comprising:
preparing a liquid metal mixture;
forming a first pattern on a substrate with the liquid metal mixture; and
forming a second pattern by pressing or heating the first pattern, wherein,
the preparing of the liquid metal mixture comprises,
mixing a polymer powder and a liquid metal to coat particles of the polymer powder with the liquid metal, and
the second pattern comprises the polymer powder and the liquid metal, and
the liquid metal fills a space among the particles of the polymer powder.

11. The method of claim 10, wherein the polymer powder comprises a polymer having a polar functional group.

12. The method of claim 10, wherein the forming of the first pattern on the substrate is performed by supplying the liquid metal mixture through a dispensing, screen printing, bar coating, or ink-jet printing method.

13. The method of claim 10, wherein the substrate comprises a trench, and the second pattern fills the trench.

14. The method of claim 10 further comprising forming an adhesive layer on the substrate, wherein the second pattern is formed on the adhesive layer.

15. The method of claim 10, wherein the liquid metal is included in an amount of about 10 to about 90 wt % and the polymer powder is included in an amount of about 10 to about 90 wt % in the liquid metal mixture.

16. The method of claim 10, wherein the pressing of the first pattern is performed by at least one method of hand pressing, lamination, and high pressure press.

17. The method of claim 10, wherein the liquid metal is selected from eutectic GaIn (EGaIn), Bi₃₅In_{48.6}Sn₁₆Zn_{0.4}, a BiInSn alloy, and a GaInSn alloy.

18. The method of claim 10, wherein the preparing of the liquid metal mixture further comprises adding a binder powder and a solvent to the polymer powder and the liquid metal, and the solvent is included in an amount of about 10 to about 100 wt % of the sum of the weight of the polymer powder and the weight of the liquid metal.

19. The method of claim 10, wherein
the polymer powder comprises a thermoplastic polymer,
the heating of the first pattern connects the particles of the thermoplastic polymer to each other, and the method further comprises cooling the second pattern.

20. The method of claim 19, wherein the forming of the first pattern and the forming of the second pattern are simultaneously performed by a 3D printer.
